(19) United States
(12) Patent Application Publication
(10) Pub. No.: US 2009/0173381 A1
(43) Pub. Date: Jul. 9, 2009

(54) GEL TYPE ELECTROLYTE FOR DYE SENSITIZED SOLAR CELL, METHOD OF PREPARING THE SAME, AND SOLAR CELL INCLUDING THE GEL TYPE ELECTROLYTE

(75) Inventors: Moon-sung KANG, Yongin-si (KR); Ji-won Lee, Yongin-si (KR); Mi-jeong Song, Yongin-si (KR); Byong-cheol Shin, Yongin-si (KR); Tae-gon Kim, Seoul (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/201,582

(22) Filed: Aug. 29, 2008

(30) Foreign Application Priority Data
Jan. 8, 2008 (KR) 2008-2336

(51) Int. Cl. H01L 31/00

(52) U.S. Cl. 136/256

(57) ABSTRACT

A gel type electrolyte for a dye-sensitized solar cell including: phosphor particles or phosphor particles with metal oxide particles; a redox couple; and an organic solvent, a method of preparing the same, and a solar cell including the gel type electrolyte, which provide for a dye-sensitized solar cell that has long-term stability, excellent photoavailability, and high ionic conductivity.

### CROSS-REFERENCE TO RELATED APPLICATIONS

This application claims the benefit of Korean Patent Application No. 2008-2336, filed on Jan. 8, 2008, in the Korean Intellectual Property Office, the disclosure of which is incorporated herein by reference.

### BACKGROUND OF THE INVENTION

1. Field of the Invention

Aspects of the present invention relate to a gel type electrolyte for a dye-sensitized solar cell, a method of preparing the same, and a solar cell including the gel-type electrolyte, and more particularly, to a gel type electrolyte for a dye-sensitized solar cell having long-term stability, high photoavailability, and high ionic conductivity, a method of preparing the same, and a solar cell including the gel-type electrolyte.

2. Description of the Related Art

Solar cells use solar energy to generate electric energy. Solar cells are environmentally friendly, have a practically unlimited energy source, and have long lifetimes. Examples of solar cells are silicon solar cells, semiconductor compound solar cells, and dye-sensitized solar cells.

Dye-sensitized solar cells are designed such that a dye molecule converts absorbed solar light into electrons and the dye molecule is adsorbed into a semiconductor oxide electrode having a wide specific surface area. Dye-sensitized solar cells are cheaper than silicon solar cells and semiconductor compound solar cells.

Dye-sensitized solar cells currently have a maximum cell efficiency of about 11% at 100 mW/cm². The cell efficiency (photoelectric conversion efficiency) of dye-sensitized solar cells can be improved by more efficiently using solar light applied thereto. Solar light consists of ultraviolet (UV) light, visible light, and infrared (IR) light. Currently, however, dyes used in the dye-sensitized solar cell mainly absorb visible light. Therefore, if solar light of UV and IR light regions are converted into visible light, efficiency of a solar cell can be improved.

Meanwhile, electrolytes may be categorized into liquid electrolytes, semi-solid electrolytes, and solid electrolytes, according to their states. A liquid electrolyte has high photoelectric conversion efficiency. However, the lifetime may be decreased if a solvent included therein leaks out or evaporates when the temperature outside a battery containing the solvent increases or if the battery is inappropriately sealed. The solid electrolyte does not leak or evaporate but has low photoelectric conversion efficiency.

### SUMMARY OF THE INVENTION

Aspects of the present invention provide a gel type electrolyte for a dye-sensitized solar cell including a phosphor particle, a redox couple, and an organic solvent. Aspects of the present invention also provide a method of preparing the gel type electrolyte. Aspects of the present invention also provide a solar cell including the gel type electrolyte.

According to an aspect of the present invention, there is provided a gel type electrolyte for a dye-sensitized solar cell, the gel type electrolyte comprising phosphor particles, a redox couple, and an organic solvent.

According to an aspect of the present invention, the gel type electrolyte may further include metal oxide particles. According to an aspect of the present invention, the average particle diameter of the phosphor particles may be in a range of 100 nm to 10 μm. According to an aspect of the present invention, the phosphor particle may include at least one kind of material selected from the group consisting of an inorganic phosphor and an organic phosphor.

According to an aspect of the present invention, the phosphor particles may include at least one inorganic compound selected from the group consisting of La₂O₂S:Eu, (Ba,Sr)₂SiO₄:Eu, ZnS:(Cu,Al), Sr₅(PO₄)₃:Eu, BaMgAl₁₀O₁₇:Eu, BaMg₂Al₁₆O₂₇:Eu, Sr₅(PO₄)₃Cl:Eu, (Ba,Mg)₃O.8Al₂O₃:Eu, ZnO:Zn, Zn₂SiO₄:Mn, Zn₂GeO₄:Mn, YVO₄:Eu, Y₂O₂S:Eu, 0.5MgF₂.3.5MgO.GeO₂:Mn, ZnS:Cu, and Y₂O₃:Eu. According to an aspect of the present invention, the phosphor particles may be phosphors comprising at least one kind of ion selected from the group consisting of Er³⁺, Yb³⁺, Tm³⁺, Ho³⁺, Pr³⁺, and Eu³⁺ on a host selected from the group consisting of YF₃, NaYF₄, NaLaF₄, LaF₄, BaY₂F₈, and Na₃YGe₂O₇; or the phosphors comprising at least one kind of ion selected from the group consisting of Er³⁺, Yb³⁺, Tm³⁺, Ho³⁺, Pr³⁺, and Eu³⁺.

According to an aspect of the present invention, the amount of the phosphor particles may be in a range of 30 parts by weight to 70 parts by weight based on 100 parts by weight of the gel type electrolyte. According to an aspect of the present invention, the average particle diameter of the metal oxide particles may be in a range of 10 nm to 400 nm.

According to an aspect of the present invention, the metal oxide particles may include at least one compound selected from the group consisting of TiO₂, WO₃, ZnO, Nb₂O₅, SnO₂, SiO₂, and TiSrO₃. According to an aspect of the present invention, the ratio of the phosphor particles to the metal oxide particles may be in a range of 9:1 to 1:1. According to an aspect of the present invention, the redox couple may be an iodine-based redox couple (I₃⁻/I⁻).

According to an aspect of the present invention, the gel type electrolyte may further include a cation selected from the group consisting of Li⁺, Na⁺, K⁺, Cs⁺, Mg²⁺, and Cu²⁺; or at least one cationic compound selected from the group consisting of imidazolium, tetra-alkyl ammonium, pyridinium, pyrrolidinium, pyrazolidium, isotriazolidium, and triazolium.

According to another embodiment of the present invention, there is provided a method of preparing a gel type electrolyte, the method including: preparing a liquid electrolyte comprising an iodide, iodine (I₂), and an organic solvent; mixing the liquid electrolyte and phosphor particles to prepare a fluorescent substance-containing compound; and centrifuging the fluorescent substance-containing mixture to isolate a gel type electrolyte.

According to an aspect of the present invention, the method may further include mixing the fluorescent substance-containing mixture and metal oxide.

According to another embodiment of the present invention, there is provided a dye-sensitized solar cell including: a semiconductor electrode including: a conductive transparent substrate, and a light absorption layer comprising metal oxide and dye disposed on a rear surface of the conductive transparent substrate; a counter electrode facing the light absorption layer of the semiconductor electrode; and the gel type electrolyte disposed between the semiconductor electrode and the counter electrode.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic sectional view of a dye-sensitized solar cell;

FIG. 2 is a schematic view illustrating an operational principle of a dye-sensitized solar cell;

FIGS. 3A and 3B schematically show photoelectric conversion characteristics of phosphor particles included in a gel type electrolyte according to an embodiment of the present invention;

FIG. 4 schematically illustrates the light scattering effect and ion conductivity effect of a gel type electrolyte according to an embodiment of the present invention; and

FIG. 5 is a graph of light current with respect to light voltage of dye-sensitized solar cells including the electrolytes prepared according to Examples 1 to 3 and Comparative Example.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures. It is understood that when an element is referred to as being “electrically connected” to or “disposed on” another element, it may be directly connected to or disposed on the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

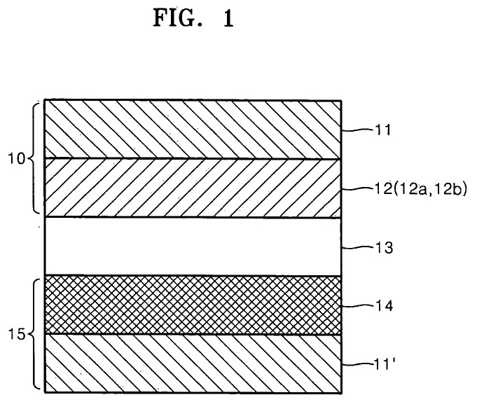

Aspects of present invention will now be described more fully with reference to the accompanying drawings, in which exemplary embodiments of the invention are shown. FIG. 1 is a schematic sectional view of a dye-sensitized solar cell. Referring to FIG. 1, the dye-sensitized solar cell includes a semiconductor electrode 10, an electrolyte layer 13, and a counter electrode 15. The semiconductor electrode 10 includes a conductive transparent substrate 11 and a light absorption layer 12, and the light absorption layer 12 includes metal oxide 12a and dye 12b. The counter electrode 15 includes a catalyst layer 14. In some cases, the counter electrode 15 may further include a conductive transparent substrate 11′.

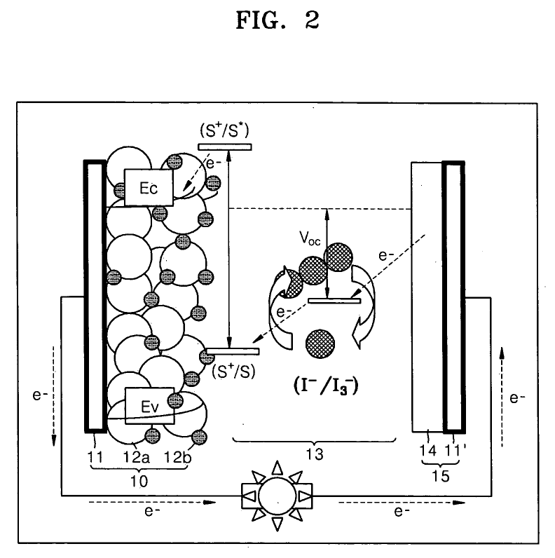

FIG. 2 is a schematic view illustrating an operating principle of a conventional dye-sensitized solar cell. Referring to FIG. 2, a dye 12b absorbs solar light and thus, an electron of the dye 12b transitions from a ground state to an excited state to form an electron-hole couple. The excited electron is injected into a conduction band in a grain boundary of the metal oxide 12a. The injected electron is transferred to the conductive transparent substrate 11 through the conduction band and then on to the counter electrode 15 through an external circuit. Meanwhile, the dye 12b oxidized as a result of the electron transition is reduced by an iodine-based redox couple (I₃⁻/I⁻) in the electrolyte layer 13 and the oxidized iodine-based redox couple performs a reduction reaction with the electron arriving at the counter electrode 15 to obtain charge neutrality. The dye-sensitized solar cell operates according to the operating principle described above.

An electrolyte used according to aspects of the present invention is a gel type electrolyte. The gel type electrolyte may include phosphor particles and an organic solvent including a redox couple. Alternatively, the gel type electrolyte may include phosphor particles, metal oxide particles, and an organic solvent including a redox couple. Unlike a liquid electrolyte, such a gel type electrolyte does not leak out and/or evaporate, and thus its long-term stability can be improved compared to the liquid electrolyte.

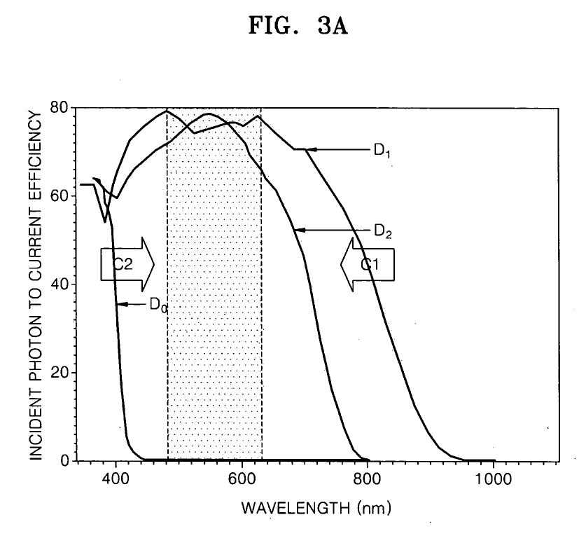

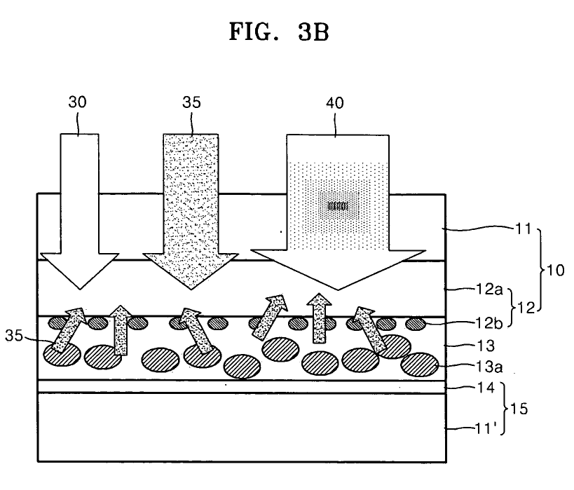

Referring to FIG. 3A, D₀ represents the photoelectric conversion characteristics of a solar cell that does not include dye, and D1 and D2 represent conventional dye-sensitized solar cells that use black dye and N₃ dye, respectively. As can be seen from D1 and D2, a conventional dye-sensitized solar cell can absorb visible light having a wavelength in a range of 400 to 800 nm, specifically, in a range of 400 to 650 nm, so as to exhibit maximum light current efficiency and is sensitized by exposure only to the visible portion of solar light by the dye 12b included in the light absorption layer. However, a dye-sensitized solar cell according to aspects of the present invention includes phosphor particles in a gel type electrolyte, and the phosphor particles can up-convert UV light or visible light in proximity to UV light, having a wavelength of 400 nm or less, into light having a wavelength in a visible light region, which is denoted by an arrow C2 of FIG. 3A; or down-convert IR light or visible light in proximity to IR light, having a wavelength of 800 nm or more, into light having a wavelength in a visible light region, which is denoted by an arrow C1 of FIG. 3A. That is, in a dye-sensitized solar cell according to aspects of the present invention, as illustrated in FIG. 3B, UV light 30 and/or IR light 40 of the incident solar light are converted into visible light 35 by a fluorescent substance so that the dye 12b can be sensitized by exposure to the converted light. Thus, incident solar light can be more effectively used.

Up-conversion phosphor particles which can be used according to aspects of the present invention may be YF₃:Yb³⁺,Er³⁺; NaYF₄:Yb³⁺,Er³⁺; NaLaF₄:Yb³⁺,Er³⁺; LaF₄:Yb³⁺,Er³⁺; BaY₂F₈:Yb³⁺,Er³⁺; or Na₃YGe₂O₇:Yb³⁺, Er³⁺, but are not limited thereto. Down-conversion phosphor particles which can be used according to aspects of the present invention may be (Sr,Ba,Ca)₂Si₅N₈:Eu²⁺; CaAlSiN₃:Eu²⁺; BaMgAl₁₀O₁₇:Eu²⁺; BaMgAl₁₀O₁₇:Eu²⁺,Mn²⁺; SiAlON:Eu²⁺; (Ca,Sr,Ba)₂P₂O₇:Eu²⁺; (Ca,Sr,Ba)₂P₂O₇:Eu²⁺,Mn²⁺; (Ca,Sr,Ba)₅(PO₄)₃Cl:Eu²⁺; Lu₂SiO₅:Ce³⁺; (Ca,Sr,Ba)₃SiO₅:Eu²⁺; (Ca,Sr,Ba)₂SiO₄:Eu²⁺; (Ca,Sr,Ba)₁₀(PO₄)₆.nB₂O₃:Eu²⁺; Sr₄Al₁₄O₂₅:Eu²⁺; or 3.5MgO.0.5MgF₂.GeO₂:Mn⁴⁺ but are not limited thereto.

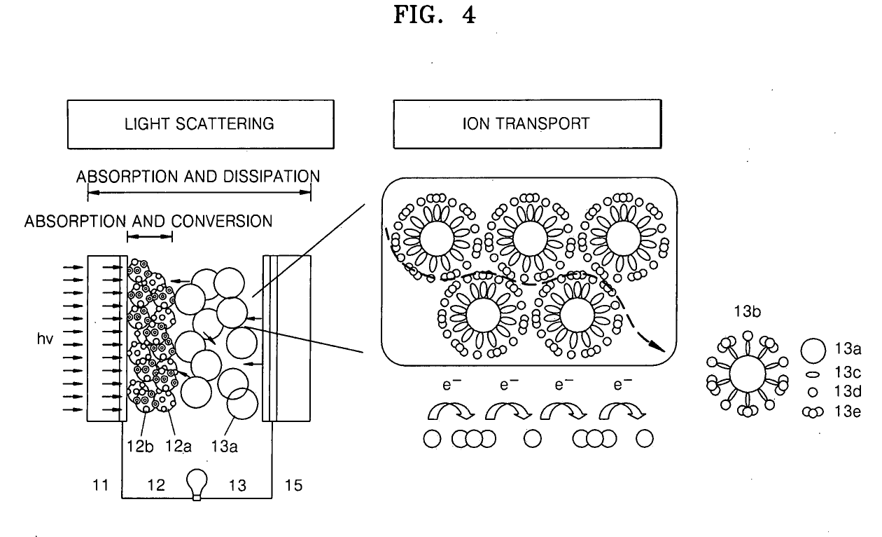

FIG. 4 schematically illustrates light scattering of the fluorescent substance and ion delivery in a gel type electrolyte in the dye-sensitized solar cell according to an embodiment of the present invention. Referring to FIG. 4, a dye-sensitized solar cell is operated in a way that among light passing through the conductive transparent substrate 11, light having a wavelength in a range of 400 to 800 nm is absorbed by the dye 12b and transferred to the metal oxide 12a, and electrons are generated. Meanwhile, light that is not absorbed by the dye 12b of the light absorption layer 12 is scattered by the fluorescent substance or the metal oxide particles 13a included in the gel type electrolyte 13 according to an embodiment of the present invention to return to the dye 12b of the semiconductor electrode 10. Therefore, incident solar light can be more efficiently used.

An enlarged view of the gel type electrolyte according to aspects of the present invention is illustrated on the right of FIG. 4. In the gel type electrolyte, cationic compounds 13c are adsorbed into the surface of the phosphor particles or metal oxide particles 13a. Meanwhile, at the end of the cationic compound 13c, negatively charged iodide redox couples 13d and 13e exist by electrical bonding. Thus, an organic and inorganic complex 13b, which consists of the phosphor particles or metal oxide particles 13a, the cationic compound 13c, and redox couples 13d and 13e together, form a pathway through which charged ions flow. Specifically, the organic and inorganic complex 13b forms a more regular structure than can be found in a gel type polymer electrolyte using a conventional polymer, and thus ions can move more easily because there are smaller obstacles in their way. That is, as denoted by a dotted arrow (- - -) in FIG. 4, ions move along the surface of the organic and inorganic complex 13b to have easy access to the layer including metal oxide (12a). As a result, high conductivity can be obtained.

The phosphor included in a gel type electrolyte according to an embodiment of the present invention may be any phosphor that is conventionally used in the art. Specifically, the phosphor can be any material that has fluorescent or phosphorescent properties. For example, the phosphor can be an organic fluorescent substance, an inorganic fluorescent substance, or an organic phosphorescent substance, which are used in fluorescent lamps and Braun tubes. More specifically, the phosphor may be a material that emits light having a wavelength of 400 nm to 650 nm, i.e., light capable of being absorbed by the dye-sensitized solar cell according to aspects of the present invention, and may be an inorganic compound represented by La₂O2S:Eu, (Ba,Sr)₂SiO₄:Eu, ZnS:(Cu,Al), Sr₅(PO₄)₃:Eu, BaMgAl₁₀O₁₇:Eu, BaMg₂Al₁₆O₂₇:Eu, Sr₅(PO₄)₃Cl:Eu, (Ba,Mg)₃O.8Al₂O₃:Eu, ZnO:Zn, Zn₂SiO₄:Mn, Zn₂GeO₄:Mn, YVO₄:Eu, Y₂O₂S:Eu, 0.5MgF₂.3.5MgO.GeO₂:Mn, ZnS:Cu, or Y₂O₃:Eu, specifically BaMgAl₁₀O₁₇:Eu, La₂O₂S:Eu, (Ba,Sr)₂SiO₄:Eu, or Sr₅(PO₄)3Cl:Eu.

The phosphor may be obtained by doping at least one kind of ion selected from the group consisting of Er³⁺, Yb³⁺, Tm³⁺, Ho³⁺, Pr³⁺ and Eu³⁺ on a host selected from the group consisting of YF₃, NaYF₄, NaLaF₄, LaF₄, BaY₂F₈, and Na₃YGe₂O₇. Alternatively, the phosphor may be an organic phosphor substance including at least one ion selected from the group consisting of Er³⁺, Yb³⁺, Tm³⁺, Ho³⁺, Pr³⁺, and Eu³⁺.

Particles of the phosphor may have an average diameter of 100 nm to 10 μm so that easy gelling is obtained and incident solar light is easily dispersed. In the gel type electrolyte according to an embodiment of the present invention, the amount of the phosphor particles may be in a range of 30 to 70 parts by weight based on 100 parts by weight of the gel type electrolyte. When the phosphor particles are included in such a range, optimal photoelectric efficiency can be obtained.

The metal oxide included in the gel type electrolyte according to an embodiment of the present invention may be the same as a metal oxide that is used in a semiconductor electrode. For example, the metal oxide may include at least one metal oxide selected from the group consisting of TiO₂, WO₃, ZnO, Nb₂O₅, SnO₂ and TiSrO₃. However, the metal oxide used in the gel type electrolyte according to an embodiment of the present invention may have an average particle diameter of 10 nm to 400 nm so as to form an organic and inorganic complex having an appropriate size to facilitate ion delivery.

The gel type electrolyte according to an embodiment of the present invention may further include a reversible redox couple. Such a redox couple may be formed from a halogen molecule and halogen salt, such as I₂ and I⁻ salt or Br₂ and Br⁻ salt; or hydroquinone/quinone. For example, the redox couple may be formed from I₂ and I⁻ salt. I₂ and I⁻ salt forms an iodide redox couple (I⁻/I₃⁻) in the gel type electrolyte according to aspects of the present invention

A cation that can forms an iodide salt and bromide salt may be a metallic cation selected from the group consisting of Li⁺, Na⁺, K⁺, Cs⁺, Mg²⁺, and Cu²⁺; or a cationic compound, such as quaternary ammonium, imidazolium, or pyridinium. For example, such a cation may be the cationic compound. Specifically, the cationic compound may be imidazolium, tetra-alkyl ammonium, pyridinium, pyrrolidinium, pyrazolidium, isotriazolidium, or triazolium, but is not limited thereto. The Iodide salt that is used to form the redox couple included in the gel type electrolyte according to an embodiment of the present invention may be n-methylimidazolium iodine, n-ethylimidazolium iodine, 1-benzyl-2-methylimidazolium iodine, 1-ethyl-3-methylimidazolium iodine, 1-butyl-3-methylimidazolium iodine, 1-methyl-3-propylimidazolium iodine, 1-methyl-3-isopropylimidazolium iodine, 1-methyl-3-butylimidazolium iodine, 1-methyl-3-isobutylimidazolium iodine, 1-methyl-3-s-butylimidazolium iodine, 1-methyl-3-pentylimidazolium iodine, 1-methyl-3-isopentylimidazolium iodine, 1-methyl-3-hexylimidazolium iodine, 1-methyl-3-isohexylimidazolium iodine, 1-methyl-3-octylimidazolium iodine, 1,2-dimethyl-3-propylimidazolium iodine, 1-ethyl-3-isopropylimidazolium iodine, 1-propyl-3-propylimidazolium iodine, or a combination thereof.

The gel type electrolyte according to an embodiment of the present invention may further include an organic solvent, such as a less-volatile solvent having a boiling point of 130° C. or more or a non-volatile solvent having a boiling point of 200° C. or more. The less-volatile solvent may be methoxypropionitril, ethylenecarbonate, propylenecarbonate, gamma-butyrolactone, dimethylformamide, diethylcarbonate, dimethylcarbonate, or a combination thereof. The non-volatile solvent may be a fused liquid (ionic liquid) at ambient-temperature including a cation selected from the group consisting of quaternary ammonium salt, imidazolium salt, and pyridinium salt and an anion selected from the group consisting of Br⁻, Cl⁻, BF₄⁻, PF₆⁻, SbF₆⁻, CF₃SO₃⁻, and (CF₃SO₂)₂N⁻; or a low molecular weight-poly alkylene oxide-based oligomer including at least one compound selected from the group consisting of polyethyleneglycol dimethylether, polyethyleneglycol diethylether, polyethyleneglycol dipropylether, polyethyleneglycol dibutylether, polyethyleneglycol diglycidylether, polypropyleneglycol dimethylether, polypropyleneglycol diglycidylether, a polypropyleneglycol/polyethyleneglycol copolymer having a terminal dibutylether, and a polyethyleneglycol/polypropyleneglycol/polyethyleneglycol block copolymer having a terminal dibutylether.

A method of preparing a gel type electrolyte according to an embodiment of the present invention will now be described in detail. The method of preparing a gel type electrolyte according to the present invention includes: preparing a liquid electrolyte including iodide salt, iodine (I₂), and an organic solvent; mixing the resultant solution with phosphor particles or with phosphor particles and metal oxide particles to prepare a liquid electrolyte; and then centrifuging the obtained liquid electrolyte to separate into a liquid phase and a solid phase. In addition, polyethyleneoxide (PEO) or poly(vinylidene fluoride)hexafluoropropylene (PVDF-HFP) can be added to the liquid electrolyte so that the liquid electrolyte gels.

Aspects of the present invention also provide a dye-sensitized solar cell including the gel type electrolyte prepared described above. A dye-sensitized solar cell according to aspects of the present invention, as illustrated in FIG. 1, includes a conductive semiconductor electrode 10, an electrolyte layer 13, and a counter electrode 15. Specifically, the semiconductor electrode 10 includes a conductive transparent substrate 11 and a light absorption layer 12, and the counter electrode 15 includes a catalyst layer 14. In some cases, the counter electrode 15 may further include, in addition to the catalyst layer 14, a conductive transparent substrate 11′.

The conductive transparent substrates 11 and 11′ may each be any kind of transparent substrate. For example, the conductive transparent substrates 11 and 11′ can be glass substrates. A material that makes the transparent substrates 11 and 11′ conductive may be any material that is conductive and transparent. In terms of conductivity, transparency, and heat-resistance properties, a tin-based oxide, such as SnO₂, is suitable as such a material. In terms of costs, ITO is suitable as such a material.

A metal oxide 12a included in the light absorption layer 12 according to aspects of the present invention may be of an elementary semiconductor, a compound semiconductor, or a perovskite (CaTiO₃) metal oxide composite. The semiconductor may be an n-type semiconductor in which a conduction-band electron is converted into a carrier when excited by light to provide an anode current. For example, the semiconductor may be TiO₂, SnO₂, ZnO, WO₃, Nb₂O₅, or TiSrO₃, and specifically TiO₂. The semiconductor is not limited to such compounds, and such compounds can be used alone or in combination. Such a semiconductor may have a large specific surface area so to increase light. In this regard, the diameter of particles of the semiconductor may be 20 nm or less, and specifically, in a range of 5 to 20 nm.

The dye 12b included in the light absorption layer 12 according to aspects of the present invention may be any substance that is used in solar cells or photocells. For example, the dye 12b may be ruthenium (Ru) complex. The Ru complex may be RuL₂(SCN)₂, RuL₂(H₂O)₂, RuL₃, or RuL₂ where L is 2,2′-bipyridyl-4,4′-dicarboxylate.

However, any dye that has a charge separation capability and is sensitized when exposed to solar light can also be used according to aspects of the present invention. For example, the dye 12b can be, in addition to the Ru complex, an xanthene type pigment, such as rhodamine B, rose gengal, eosine, or erythrosine; a cyanine-type pigment, such as quinocyanine or cryptocyanine; a basic dye, such as phenosafranine, Capri blue, thiocine, or methyleneblue; chlorophyl; a porphyrin-based compound, such as zinc porphyrin, or magnesium porphyrin; other azo pigments; a complex compound, such as a phthalocyane compound or Ru trisbipyridiyl; antraquinone-based pigment; or polycyclic quinine-based pigment. Such compounds may be used alone or in combination.

The thickness of the light absorption layer 12 including the metal oxide 12a and the dye 12b may be 15 microns or less, and specifically, 5 to 15 microns. The light absorption layer 12 has a large series resistance due to its structure and such an increase in a series resistance leads to a decrease in conversion efficiency. Therefore, by forming the light absorption layer to a thickness of 12 to 15 microns or lower, conversion efficiency can be improved by keeping the series resistance sufficiently low.

The gel type electrolyte according to aspects of the present invention can be used as the electrolyte layer 13. The light absorption layer 12 may be immersed in the gel type electrolyte, or the gel type electrolyte may permeate into the light absorption layer 12. Although the gel type electrolyte includes an organic solvent, most of the organic solvent can be evaporated in the manufacturing process.

The counter electrode 15 may be formed of any material that is conductive. The counter electrode 15 can also be formed of an insulating material when the conductive layer is formed on a surface of the counter electrode 15 that faces the semiconductor electrode 10. Such materials may be electrochemically stable. Specifically, the counter electrode 15 may be formed of Pt, Au, or C. In addition, to improve catalytic effect to the redox reactions, the surface of the counter electrode 15 that faces the semiconductor electrode 10 may have a micro structure having a large surface area. For example, the counter electrode 15 may be formed of Pt black or a porous carbon. Pt black can be formed by cathode oxidation of Pt or treatment with chloroplatinic acid. Porous carbon can be formed by sintering of carbon particles or sintering of an organopolymer.

Aspects of the present invention will be described in further detail with reference to the following examples. These examples are for illustrative purposes only and are not intended to limit the scope of the aspects of the present invention.

### EXAMPLES

### Example 1

### Preparation of Gel Type Electrolyte

Butylmethylimidazolium iodide (BMNIml, 0.8M) and iodine (I₂, 0.1M) were dissolved in 3-methoxypropionitrile (MPN), which is a less-volatile solvent, to prepare a liquid electrolyte. The resultant liquid electrolyte was mixed with BaMgAl₁₀O₁₂:Eu²⁺ (from Kasei Opt, Japan) and metal oxide particles TiO₂ (P-25, particle diameter of 20 to 25 nm) in a weight ratio of 5:5 and then stirred together to prepare a 10 weight % suspension. The obtained suspension was sufficiently milled to uniformly disperse the solid particles. Then, the resultant suspension was centrifuged at 2,000 rpm for 10 minutes. The resultant was separated from the liquid phase to obtain a gel type electrolyte.

### Example 2

### Preparation of Gel Type Electrolyte

A gel type electrolyte was obtained in the same manner as in Example 1, except that phosphor particles and metal oxide particles were mixed in a ratio of 7:3.

### Example 3

### Preparation of Gel Type Electrolyte

A gel type electrolyte was obtained in the same manner as in Example 1, except that the 10 weight % of suspension was prepared using phosphor particles alone.

### Comparative Example

### Preparation of Liquid Electrolyte

Liquid electrolyte was prepared by dissolving butylmethylimidazolium iodide 0.8M and iodine 0.1M in 3-methoxypropionitirle (MPN), which is a less-volatile solvent.

<Preparation of Dye-Sensitized Solar Cell>

A dispersion solution of titanium oxide particles having a particle diameter of 20-25 nm was coated on an indium-doped tin oxide transparent conductor using a doctor blade in an area of 1 cm², then heat treatment and sintering processes were performed at 450° C. for three minutes to form a 15 μm-thick porous titanium oxide layer. Then, the sample was left to sit at 80° C. and then a dye adsorption treatment was performed using a 0.3 mM [Ru(dcb)₂(dfo)] (CN)₂ dye pigment solution in which methanol was dissolved for 12 hours or more. Then, the dye-adsorbed porous titanium oxide layer was cleansed with methanol and dried at room temperature to manufacture a semiconductor electrode.

To prepare a counter electrode, a Pt layer was deposited by sputtering on an indium-doped tin oxide transparent conductor, and then small pores were formed therein using a 0.75 mm-diameter drill to inject the electrolyte therein.

A 60 μm-thick thermoplastic polymer film was placed between the semiconductor electrode and the counter electrode, and then the resultant structure was compressed at 100° C. for 9 seconds so that two electrodes were combined with each other. The electrolytes prepared according to Examples 1 to 3 and Comparative Example were injected through the fine pores formed in the counter electrode, and then the fine pores were sealed using a cover glass and a thermoplastic film, thereby completing manufacture of a dye-sensitized solar cell.

<Photoelectric Conversion Characteristics>

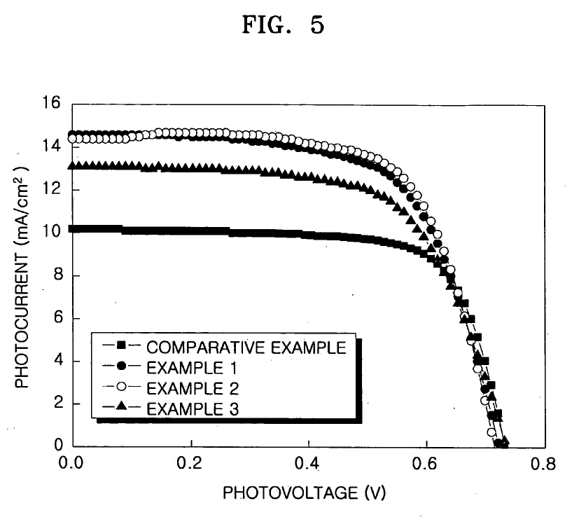

The photovoltage and photocurrent of the dye-sensitized solar cells prepared according to Examples 1-3 and Comparative Example were measured to identify photoelectric conversion characteristics. The results of photocurrent (mA/cm²) versus photovoltage (V) for Examples 1-3 and Comparative Example are shown in FIG. 5. With reference to FIG. 5, a shortcut current (J_{sc}), an open voltage (V_{oc}), a fill factor, (FF), and photoelectric conversion efficiency (Eff) were measured. These values are shown in Table 1.

A light source used was a xenon lamp (Oriel, 01193), and a solar light condition (AM 1.5) of the xenon lamp was adjusted with reference to a standard solar cell (Frunhofer Institute Solare Engeriessysteme, Certificate No. C-ISE369, Type of material: Mono-Si+KG filter).

TABLE 1

| | Jsc | Voc | FF | Eff/% |
|---|---|---|---|---|
| Example 1 | 14.6 | 0.722 | 65.1 | 6.86 |
| Example 2 | 14.38 | 0.714 | 69.1 | 7.10 |
| Example 3 | 13.11 | 0.734 | 64.4 | 6.19 |
| Comparative | 10.18 | 0.732 | 72.5 | 5.40 |
| Example | | | | |

Referring to FIG. 5 and Table 1, when the gel type electrolytes prepared according to Examples 1-3 were used, the obtained dye-sensitized solar cells showed higher photoelectricity currents and better photoelectricity characteristics than when the liquid electrolyte prepared according to Comparative Example was used, which may have resulted from the photo scattering effect and light wavelength conversion effect of the phosphor particle. In addition, with respect Examples 1-3, when metal oxide particles were used in addition to phosphor particle, dye-sensitized solar cells showed high photoelectricity currents. Such results may be due to the fact that metal oxide particles provide better ion pathways than phosphor particles, and thus, the ionic conductivity of the gel type electrolytes prepared according to Examples 2 and 3 is improved.

Although a few embodiments of the present invention have been shown and described, it would be appreciated by those skilled in the art that changes may be made in this embodiment without departing from the principles and spirit of the invention, the scope of which is defined in the claims and their equivalents.

1. A gel type electrolyte for a dye-sensitized solar cell, comprising:
a phosphor particle to absorb ultraviolet light and/or infrared light and emit light having a wavelength in a visible light region;
a redox couple to donate and/or accept electrons to maintain a net charge neutrality in the gel type electrolyte; and
an organic solvent.

2. The gel type electrolyte of claim 1, further comprising metal oxide particles.

3. The gel type electrolyte of claim 1, wherein the average particle diameter of the phosphor particles is 100 nm to 10 μm.

4. The gel type electrolyte of claim 1, wherein the phosphor particles comprise at least one material selected from the group consisting of an inorganic phosphor and an organic phosphor.

5. The gel type electrolyte of claim 1, wherein the phosphor particles comprise at least one inorganic compound selected from the group consisting of La₂O₂S:Eu, (Ba,Sr)₂SiO₄:Eu, ZnS:(Cu,Al), Sr₅(PO₄)₃:Eu, BaMgAl₁₀O₁₇:Eu, BaMg₂Al₁₆O₂₇:Eu, Sr₅(PO₄)₃Cl:Eu, (Ba,Mg)₃O.8Al₂O₃:Eu, ZnO:Zn, Zn₂SiO₄:Mn, Zn₂GeO₄:Mn, YVO₄:Eu, Y₂O₂S:Eu, 0.5MgF₂.3.5MgO.GeO₂:Mn, ZnS:Cu, and Y₂O₃:Eu.

6. The gel type electrolyte of claim 1, wherein the phosphor particles comprise at least one ion selected from the group consisting of Er³⁺, Yb³⁺, Tm³⁺, Ho³⁺, Pr³⁺, and Eu³⁺; and
a host selected from the group consisting of YF₃, NaYF₄, NaLaF₄, LaF₄, BaY₂F₈, and Na₃YGe₂O₇.

7. The gel type electrolyte of claim 1, wherein the phosphor particles comprise at least one kind of ion selected from the group consisting of Er³⁺, Yb³⁺, Tm³⁺, Ho³⁺, Pr³⁺, and Eu³⁺.

8. The gel type electrolyte of claim 1, wherein the amount of the phosphor particles is in a range of 30 parts by weight to 70 parts by weight based on 100 parts by weight of the gel type electrolyte.

9. The gel type electrolyte of claim 2, wherein the average particle diameter of the metal oxide particles is 10 nm to 400 nm.

10. The gel type electrolyte of claim 2, wherein the metal oxide particles comprise at least one compound selected from the group consisting of TiO₂, WO₃, ZnO, Nb₂O₅, SnO₂, SiO₂, and TiSrO₃.

11. The gel type electrolyte of claim 2, wherein a weight ratio of the phosphor particles to the metal oxide particles is 9:1 to 1:1.

12. The gel type electrolyte of claim 1, wherein the redox couple is an iodine-based redox couple (I₃⁻/I⁻).

13. The gel type electrolyte of claim 1, further comprising a cation selected from the group consisting of Li⁺, Na⁺, K⁺, Cs⁺, Mg²⁺, and Cu²⁺.

14. The gel type electrolyte of claim 1, further comprising a cation selected from at least one cationic compound selected from the group consisting of imidazolium, tetra-alkyl ammonium, pyridinium, pyrrolidinium, pyrazolidium, isotriazolidium, and triazolium.

15. A method of preparing a gel type electrolyte, the method comprising:
preparing a liquid electrolyte comprising iodide, iodine, and an organic solvent;
mixing the liquid electrolyte and phosphor particles to prepare a fluorescent substance-containing mixture; and
centrifuging the fluorescent substance-containing mixture to isolate a gel type electrolyte.

16. The method of claim 15, further comprising mixing the fluorescent substance-containing mixture and metal oxide.

17. The method of claim 15, further comprising adding polyethyleneoxide (PEO) and/or poly(vinylidene fluoride)hexafluoropropylene (PVDF-HFP) to the liquid electrolyte.

18. A dye-sensitized solar cell, comprising:
a semiconductor electrode comprising:
a conductive transparent substrate, and
a light absorption layer comprising metal oxide and dye, disposed on a rear surface of the conductive transparent substrate;
a counter electrode disposed opposite the conductive transparent substrate from the light absorption layer of the semiconductor electrode; and
the gel type electrolyte of claim 1 disposed between the semiconductor electrode and the counter electrode.

19. The dye-sensitized solar cell of claim 18, wherein the gel type electrolyte further comprises metal oxide particles.

20. The dye-sensitized solar cell of claim 18, wherein the counter electrode comprises a catalyst layer disposed adjacent to the gel type electrolyte.

21. The dye-sensitized solar cell of claim 18, wherein the light absorption layer comprises ruthenium (Ru) complex dye.
